(19) United States
(12) Patent Application Publication
(10) Pub. No.: US 2008/0173942 A1
(43) Pub. Date: Jul. 24, 2008

(54) STRUCTURE AND METHOD OF MANUFACTURING A STRAINED FinFET WITH STRESSED SILICIDE

(75) Inventors: Huilong Zhu, Poughkeepsie, NY (US); Siddhartha Panda, Beacon, NY (US); Jay W. Strane, Wappingers Falls, NY (US); Sey-Ping Sun, Poughkeepsie, NY (US); Brian L. Tessier, Poughkeepsie, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignees: INTERNATIONAL BUSINESS MACHINES CORPORATION, Armonk, NY (US); ADVANCED MICRO DEVICES, INC., Sunnyvale, CA (US)

(21) Appl. No.: 11/625,431

(22) Filed: Jan. 22, 2007

(51) Int. Cl. H01L 29/786; H01L 21/336

(52) U.S. Cl. 257/347; 438/151; 257/E29.273; 257/E21.411

(57) ABSTRACT

A stressed semiconductor structure including at least one FinFET device on a surface of a substrate, typically a buried insulating layer of an initial semiconductor-on-insulator substrate, is provided. In a preferred embodiment, the at least one FinFET device includes a semiconductor Fin that is located on an unetched portion of the buried insulator layer which has a raised height as compared to an adjacent and adjoining etched portion of the buried insulating layer. The semiconductor Fin includes a gate dielectric on its sidewalls and optionally a hard mask located on an upper surface thereof. The inventive structure also includes a gate conductor, which is located on the surface of the substrate, typically the buried insulating layer, and the gate conductor is at least laterally adjacent to the gate dielectric located on the sidewalls of the semiconductor Fin. A stressed silicide is located on the gate conductor, which introduces stress into the channel of the FinFET device. The stressed silicide memorizes the stress from a sacrificial stressed film that is formed prior to forming the stressed silicide. The stress type of the stressed film is introduced into the silicide during a silicide anneal step.

### FIELD OF THE INVENTION

The present invention relates to a semiconductor structure and a method of fabricating the same. More particularly, the present invention relates to a strained FinFET wherein a stressed silicide is used to introduce stress into the channel of the FinFET as well as a method of fabricating the same.

### BACKGROUND OF THE INVENTION

The dimensions of semiconductor field effect transistors (FETs) have been steadily shrinking over the last thirty 30 years or so, as scaling to smaller dimensions leads to continuing device performance improvements. Planar FET devices have a conducting gate electrode positioned above a semiconducting channel, and electrically isolated from the channel by a thin layer of gate oxide. Current through the channel is controlled by applying voltage to the conducting gate.

For a given device length, the amount of current drive for an FET is proportional to the device width (w). Drive current scales proportionally to device width, with wider devices carrying more current than narrower devices. Different parts of integrated circuits (ICs) require the FETs to drive different amounts of current, i.e., with different device widths, which is particularly easy to accommodate in planar FET devices by merely changing the device gate width (via lithography).

With conventional planar FET scaling reaching fundamental limits, the semiconductor industry is looking at more unconventional geometries that will facilitate continued device performance improvements. One such class of devices is a FinFET.

A FinFET is typically a double gate FET in which the channel is a semiconducting “Fin” of width w and height h, where typically w<h. The gate dielectric and gate are positioned around the Fin such that current flows down the channel on the two sides of the Fin. If the top surface of the Fin is used for part of conducting channel, it is called tri-gate FinFET.

Although FinFET technology is well known in the art, strained FinFETs are less common since it is difficult to apply large stress in the channel of FinFET devices. Similar to planar FET technology, stress can enhance electron and hole mobilities in the channel of FinFET devices such that higher performance devices are obtained.

In view of the above, there is a need for providing a semiconductor structure including at least one FinFET wherein the channel thereof is highly strained.

### SUMMARY OF THE INVENTION

The present invention provides a semiconductor structure including at least one FinFET device on a surface of a substrate, typically a buried insulating layer of an initial semiconductor-on-insulator substrate. In a preferred embodiment, the at least one FinFET device includes a semiconductor Fin that is located on an unetched portion of the buried insulator layer which has a raised height as compared to an adjacent and adjoining etched portion of the buried insulating layer. The semiconductor Fin includes a gate dielectric on its sidewalls and optionally a hard mask located on an upper surface thereof.

In some embodiments, the gate dielectric may be located atop the semiconductor Fin instead of the hard mask. The inventive structure also includes a gate conductor, which is located on the surface of a bulk substrate or, more typically, the buried insulating layer of a semiconductor-on-insulator, and the gate conductor is at least laterally adjacent to the gate dielectric located on the sidewalls of the semiconductor Fin. The conductor gate is also located atop the semiconductor Fin either separated therefrom by either the hard mask or the gate dielectric.

A stressed silicide is located on the gate conductor, which introduces stress into the channel of the FinFET device. The stressed silicide memorizes the stress from a sacrificial stressed film that is formed prior to forming the stressed silicide. The stress type of the stressed film is introduced into the silicide during a silicide anneal step.

In broad terms, the inventive structure comprises:
at least one FinFET device located on a surface of a substrate, said at least one FinFET device includes a semiconductor Fin located directly on said substrate, a gate dielectric located on at least sidewalls of said semiconductor Fin and a gate conductor located on the surface of the substrate and at least laterally adjacent to the gate dielectric located on the sidewalls of the semiconductor Fin; and
a stressed silicide located directly on the gate conductor, which introduces stress into a channel region of FinFET device.

In a preferred embodiment, the substrate is a semiconductor-on-insulator and said semiconductor Fin is located on a buried insulating layer. In such an embodiment, the gate conductor is also located on a surface of the buried insulating layer.

In addition to the above, the present invention also provides a method of fabricating such a semiconductor structure. The inventive method basically includes depositing a stressed film atop a material stack that includes, from bottom to top, a silicide metal and an etch stop layer. A silicide anneal is then performed to cause reaction between the silicide metal and an upper portion of the gate conductor that has previously been made amorphous by an amorphization ion implantation step. After annealing, the silicide that forms memorizes the stress produced by the stressed film.

In general terms, the inventive method comprises:
forming a structure including at least one FinFET device located on a surface of a substrate, typically the buried insulating layer of a semiconductor-on-insulator substrate, said at least one FinFET device including a semiconductor Fin located directly on said substrate, typically said buried insulating layer, a gate dielectric located on at least sidewalls of said semiconductor Fin and a gate conductor including an upper amorphized region located on the surface of the substrate, typically the buried insulating layer and at least laterally adjacent to the gate dielectric located on the sidewalls of the semiconductor Fin;
forming a material stack comprising, from bottom to top, a silicide metal, an etch stop layer and a stressed film on said structure; and
performing a silicide anneal that causes reaction between said silicide metal and said amorphized upper portion of said gate conductor converting the upper amorphized portion of said gate conductor into a metal silicide, said metal silicide having the same stress type as that of said stressed film.

### BRIEF DESCRIPTION OF THE DRAWINGS

FIG. 1 is a pictorial representation (through a cross sectional view) illustrating the strained FinFET structure of the present invention.

FIGS. 2-15E are pictorial representations (through various views) illustrating the basic processing steps employed in the present invention for fabricating the inventive structure.

### DETAILED DESCRIPTION OF THE INVENTION

The present invention, which provides a strained FinFET with stressed silicide as well as a method of fabricating the same, will now be described in greater detail by referring to the following discussion and drawings that accompany the present application. It is noted that the drawings of the present application are provided for illustrative purposes and, as such, they are not necessarily drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

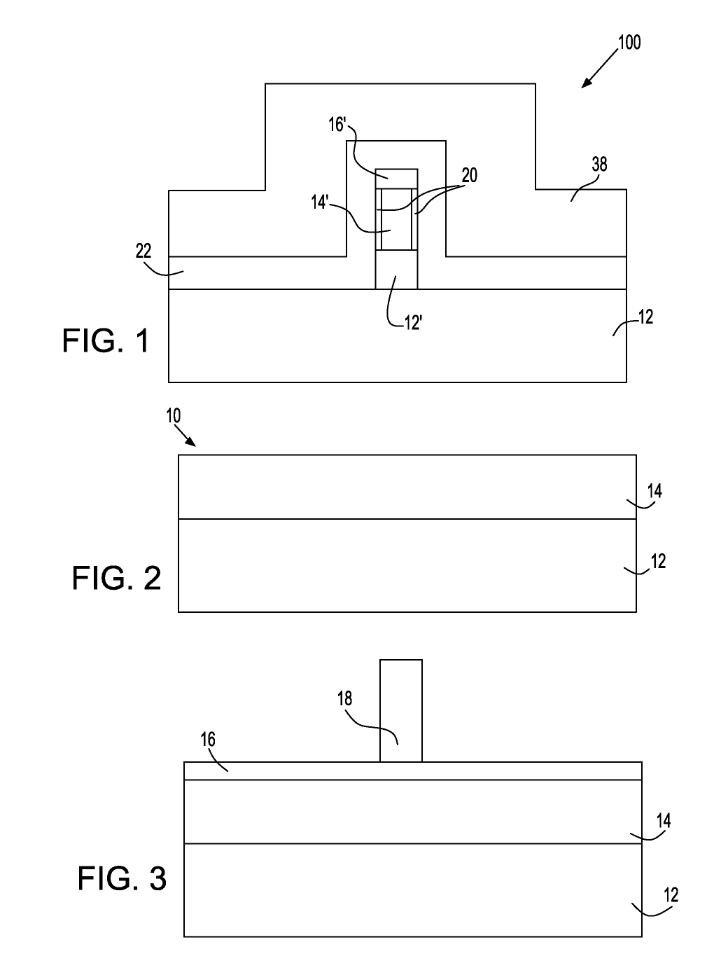

The present invention provides a semiconductor structure see FIG. 1 including at least one FinFET device 100 on an unetched or etched portion of a buried insulating layer 12. In FIG. 1, a buried insulating layer is shown which includes etched portion 12 and unetched portion 12′. A semiconductor Fin 14′ is located atop the buried insulating layer 12, particularly, the unetched portion shown in FIG. 1. The semiconductor Fin 14′ includes a gate dielectric 20 on its sidewalls and optionally a hard mask 16′ located on an upper surface thereof. In some embodiments (not shown), the gate dielectric 20 may be located atop the semiconductor Fin 14′ instead of the hard mask 16′. The FinFET device could also be located on an etch or unetched upper surface of a bulk semiconductor substrate (not specifically shown).

The inventive structure also includes a gate conductor 22 which is located on the surface of the buried insulating layer 12 and the gate conductor 22 is at least laterally adjacent to the gate dielectric 20 located on the sidewalls of the semiconductor Fin 14′. The conductor gate 22 is also located atop the semiconductor Fin 14′ either separated therefrom by the hard mask 16′ or the gate dielectric (not shown). When a bulk substrate is used, the gate conductor 22 would be located on a portion of the substrate.

A stressed silicide 38 is located on the gate conductor 22, which introduces stress into the channel of the FinFET device 100 shown in FIG. 1. The stressed silicide 38 memorizes the stress from a sacrificial stressed film that is formed prior to forming the stressed silicide. The stress type of the stressed film is introduced into the silicide during a silicide anneal step.

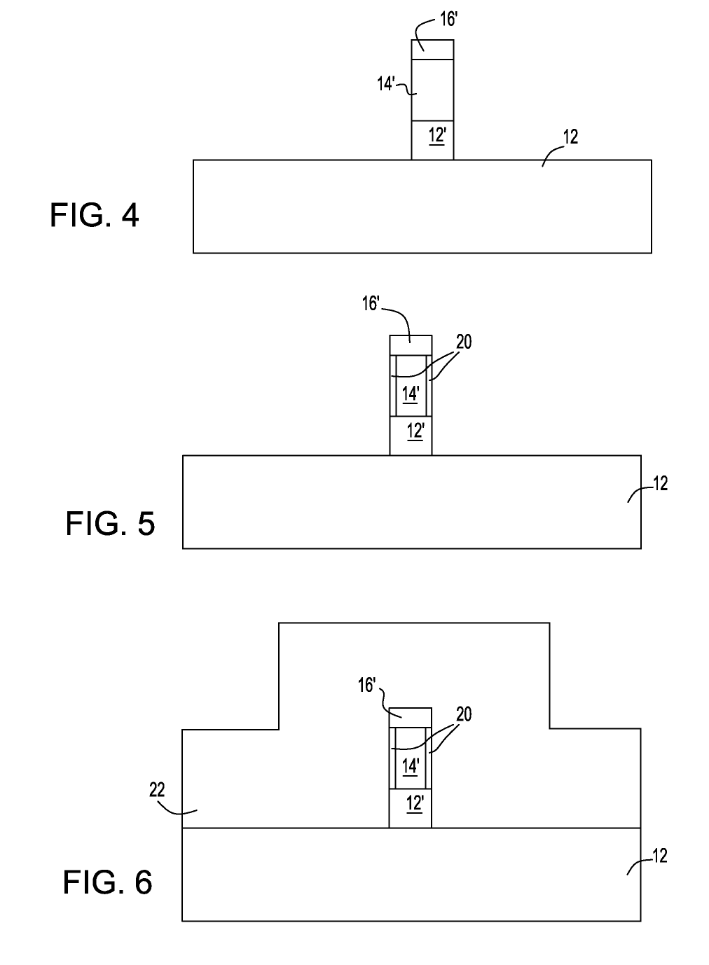

Reference is now made to FIGS. 2-15E which illustrates the basic processing steps of the present invention. The inventive process begins by providing a semiconductor-on-insulator (SOI) substrate that includes bottom and top semiconductor layers, which are separated from each other by a buried insulating layer. FIG. 2 illustrates a portion of a SOI substrate 10 that can be used in the present invention. The portion of the SOI substrate includes a buried insulating layer 12 and a top semiconductor layer 14. It is noted that although a SOI substrate is shown and illustrated, the present invention works equally well when a bulk semiconductor is used.

For clarity, the bottom semiconductor layer of the SOI substrate is not shown in FIG. 2 or the other drawings of the present invention. Although the bottom semiconductor layer is not specifically shown, one skilled in the art would invariably know that the bottom semiconductor layer is located directly beneath the buried insulating layer 12.

The term “semiconductor layer” is used throughout the present invention to denote a material that has semiconductor properties. Examples of such semiconductor materials that can be used in the present invention include, but are not limited to Si, SiGe, SiGeC, SiC, Ge alloys, GaAs, InAs, InP as well as other III/V or II/VI compound semiconductors. In one embodiment of the present invention, the semiconductor layers are Si-containing semiconductor materials such as, for example, Si or SiGe.

The buried insulating layer 12 that separates the top and bottom semiconductor layers may comprise a crystalline or non-crystalline oxide, nitride or any combination thereof. Preferably, the buried insulating layer is an oxide.

The top and bottom semiconductor layers of the SOI substrate may have the same or different crystallographic orientations. In some embodiments, the top semiconductor layer may include regions that have different crystallographic orientations. Such SOI substrates may be referred to as hybrid orientation substrates.

The SOI substrates (including the hybrid substrates) are made utilizing conventional techniques well known to those skilled in the art. For example, wafer bonding, lamination or a process referred to as separation by ion implantation of oxygen (SIMOX) can be used in forming the SOI substrates.

The top semiconductor layer 14 of the SOI substrate may have a variable thickness depending on the technique used in forming the SOI substrate. Typically, the top semiconductor layer 14 of the SOI substrate has a thickness from about 10 to about 250 nm, with a thickness from about 50 to about 100 nm being even more typical. The thickness of the buried insulating layer 12 is typically from about 10 to about 300 nm, with a thickness from about 100 to about 200 nm being even more typical.

It is noted that the top semiconductor layer 14 will be used in the present invention as a semiconductor Fin of the inventive structure. In some embodiments of the present invention, a thinning step may be performed to thin the top semiconductor layer 14 to a desired thickness that is within the ranges mentioned above. In other embodiments, an upper portion of a bulk semiconductor substrate can be used as the semiconductor Fin.

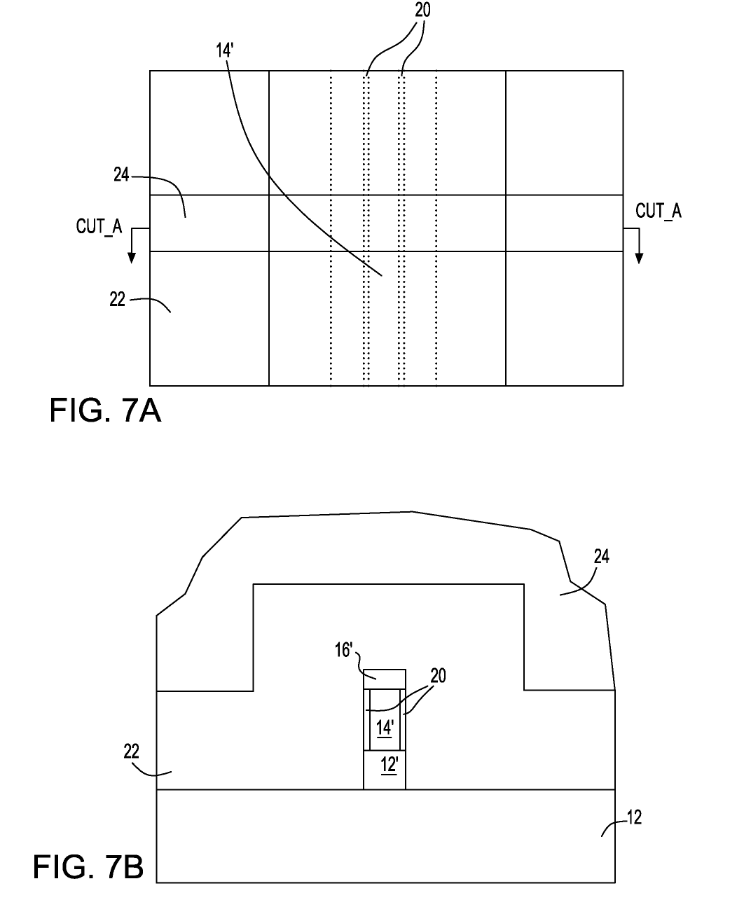

FIG. 3 illustrates the resultant structure that is formed after applying a blanket layer of hard mask material 16 on the upper exposed surface of the top semiconductor layer 14 and after forming a patterned photoresist 18 on an exposed surface of the hard mask material 16.

The hard mask material 16 employed in the present invention comprises any conventional dielectric material including, for example, an oxide, nitride, oxynitride or any multilayered stack thereof. Preferably, the hard mask material 16 is a nitride such as, for example, silicon nitride. The hard mask material 16 may be formed utilizing any conventional deposition process well known to those skilled in the art. For example, chemical vapor deposition (CVD), plasma enhanced chemical vapor deposition (PECVD), evaporation, atomic layer deposition (ALD) or chemical solution deposition may be employed. Alternatively, the hard mask material 16 may be formed by a thermal process such as, for example, oxidation and/or nitridation. Combinations of the above mentioned techniques (deposition and/or thermal) may also be used in forming the blanket layer of hard mask material 16.

The thickness of the hard mask material 16 may vary depending on the technique used in forming the same as well as the material of the hard mask itself. Typically, the hard mask material 16 has a thickness from about 10 to about 300 nm.

Next, a photoresist is applied to the surface of the hard mask material 16 utilizing a conventional deposition process including, for example, CVD, PECVD, evaporation and spin-on coating. The photoresist, which comprise an organic material, an inorganic material or a hybrid material, is then patterned by lithography. The lithographic step includes exposing the photoresist to a desired pattern of radiation and developing the exposed resist utilizing a conventional resist developer. It is noted that although a single patterned photoresist 18 is shown and illustrated, the present invention works equally well when a plurality of patterned photoresists are formed atop the hard mask material, each of which is used in defining a Fin within the top semiconductor layer 14.

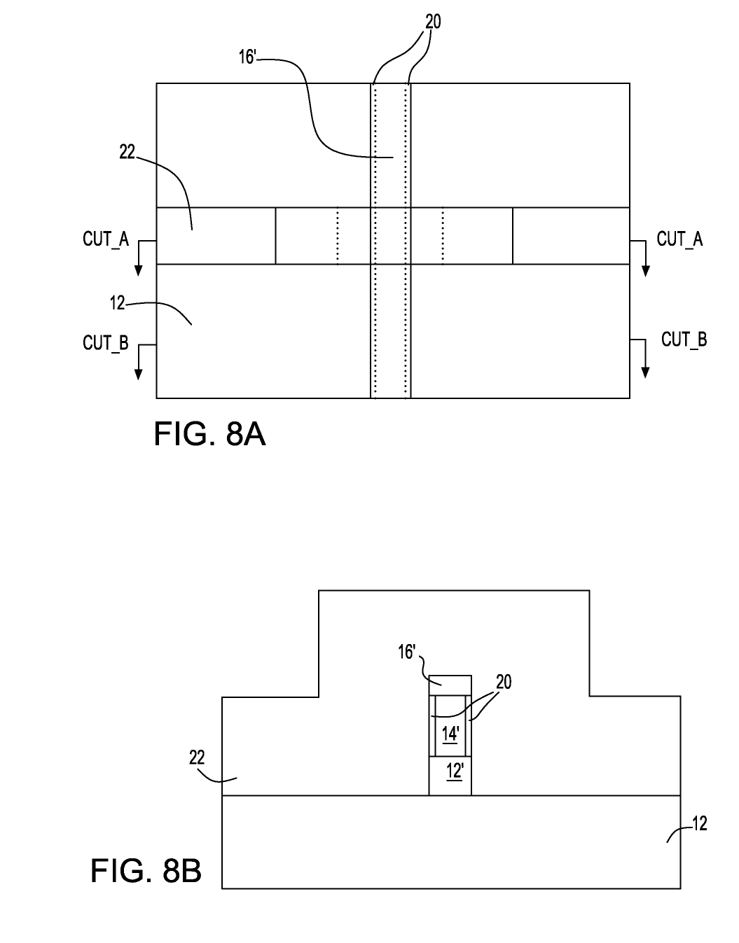

An etching process such as a timed or end-point reactive ion etching (RIE) is then performed to provide the structure shown in FIG. 4 and thereafter the patterned photoresist 18 is stripped utilizing a conventional resist stripping process. As shown, the hard mask material 16 is etched as well as the underlying top semiconductor layer 14.

Typically, but not necessarily always, the etching stops at the upper surface of the buried insulating layer 12 (not shown in the drawings of the present invention). In some embodiments, such as is shown in FIG. 4, the etching stops below the upper surface of the buried insulating layer 12. In FIG. 4, reference numeral 16′ denotes the remaining hard mask material that is not etched, while reference numeral 14′ denotes the remaining top semiconductor layer that is not etched. The region of the buried insulating layer that lies directly beneath the etched hard mask material 16′ and the etched top semiconductor layer 14′ is denoted by reference numeral 12′. In the embodiment shown, and in the case when the etching removes a portion of the buried insulating layer, a more uniform stress can be applied across the semiconductor Fin (i.e., the etched semiconductor layer 14′).

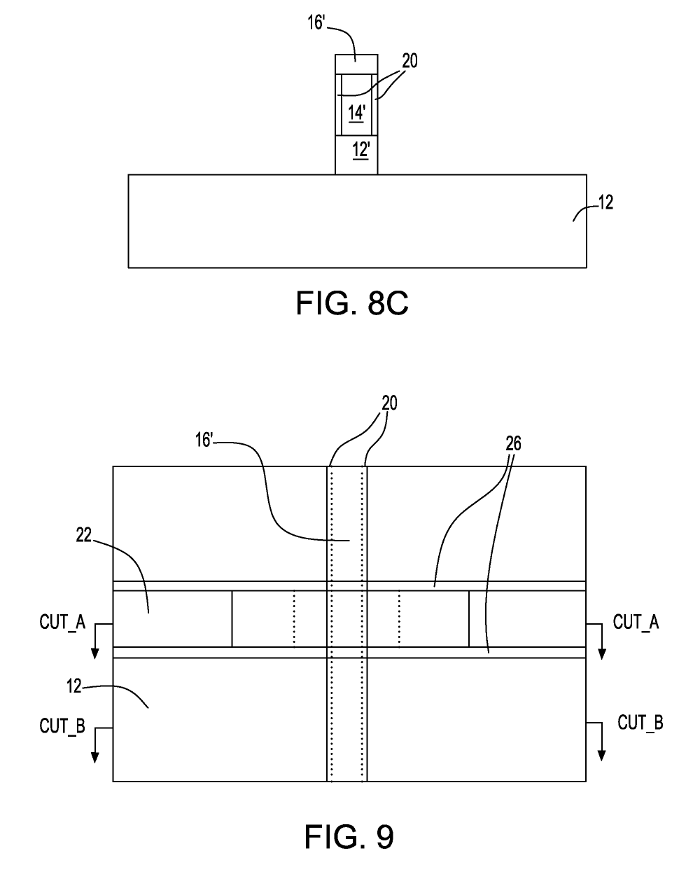

A gate dielectric 20 is then formed on at least the exposed sidewalls of the semiconductor Fin 14′. The resultant structure including the gate dielectric 20 is shown in FIG. 5. In some embodiments (not shown), the remaining hard mask material 16′ that lies atop the horizontal surface of the semiconductor Fin 14′ can be removed prior to forming the gate dielectric 20. If such an embodiment is employed, the gate dielectric 20 is also present atop the semiconductor Fin 14′. The gate dielectric 20 is formed typically, but not necessarily exclusively, by a thermal process such as, for example, thermal oxidation. In some embodiments, the gate dielectric 20 can be formed utilizing a conventional deposition process.

The gate dielectric 20 may comprise an oxide, nitride, oxynitride, or any combination including a multilayered stack of such dielectric materials. Typically, the gate dielectric 20 is an oxide (preferably a thermal oxide) such as for example silicon dioxide. Other types of oxides are also contemplated by the present invention including metal oxides and/or mixed metal oxides.

The thickness of the gate dielectric 20 may vary depending on the technique used in forming the same. Typically, the gate dielectric 20 has a thickness from about 0.5 to about 5 nm, with a thickness from about 1 to about 3 nm being even more typical. It is noted that when a thermal process is used, the thermal technique consumes portions of the semiconductor 14′ thereby reducing the lateral thickness of the original defined Fin.

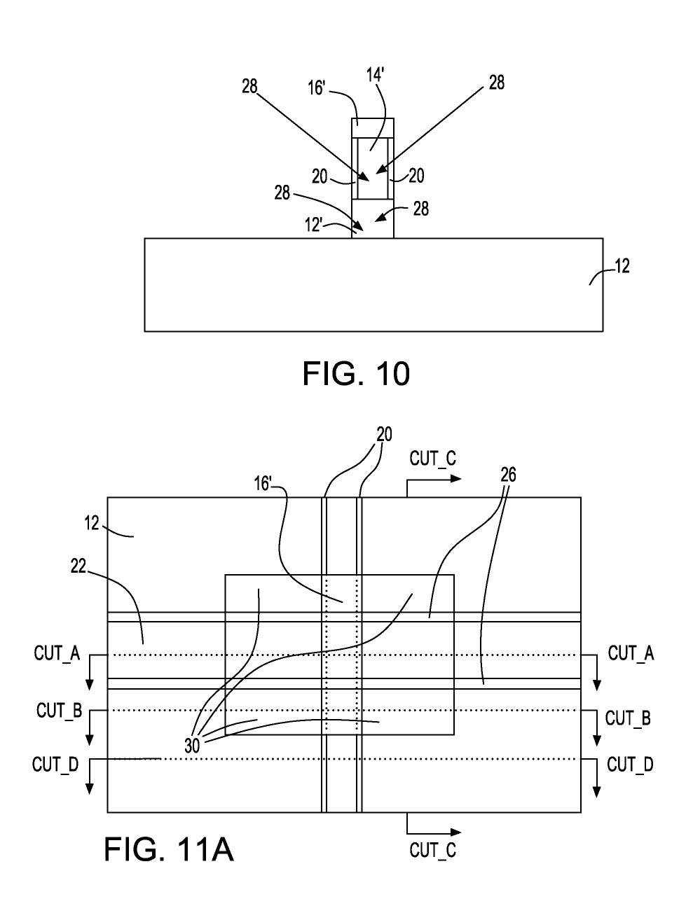

FIG. 6 shows the structure that is formed after applying a blanket layer of a gate conductor 22 to the structure shown in FIG. 5. The gate conductor 22 comprises poly Si and/or SiGe.

Gate conductor 22 can be formed utilizing any conventional technique known to those skilled in the art. For example, CVD, PECVD, evaporation, ALD, sputtering and chemical solution deposition may be employed. The poly-Si and/or SiGe material can be doped after deposition utilizing a separate ion implantation process, or an in-situ doping deposition process can be used.

The gate conductor 22 has an as deposited vertical thickness that is typically greater than that of the remaining hard mask material 16′, the semiconductor Fin 14′ and, if present, the buried insulating material 12′ that lies immediately beneath layers 16′ and 14′. Typically, the gate conductor 22 has an as deposited vertical thickness from about 50 to about 200 nm, with a thickness from about 80 to about 150 nm being even more typical.

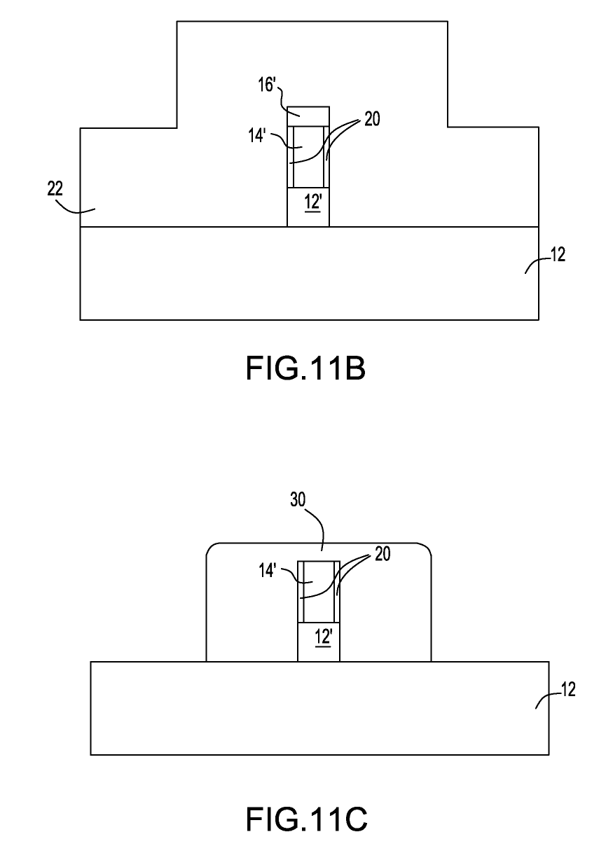

FIGS. 7A (top down view) and 7B (cross sectional view through line A-A shown in FIG. 7A) illustrate the structure that is formed after forming a patterned photoresist 24 atop the structure shown in FIG. 5. The patterned photoresist 24 is formed utilizing the same technique described above for forming the patterned photoresist used in defining the semiconductor Fin 14′. The patterned photoresist 24 is formed perpendicular to the gate dielectric 20 such as is clearly shown in the top down view of FIG. 7A. Note that the patterned photoresist 24 protects a portion of the gate conductor 22, while leaving other portions of the gate conductor 22 exposed.

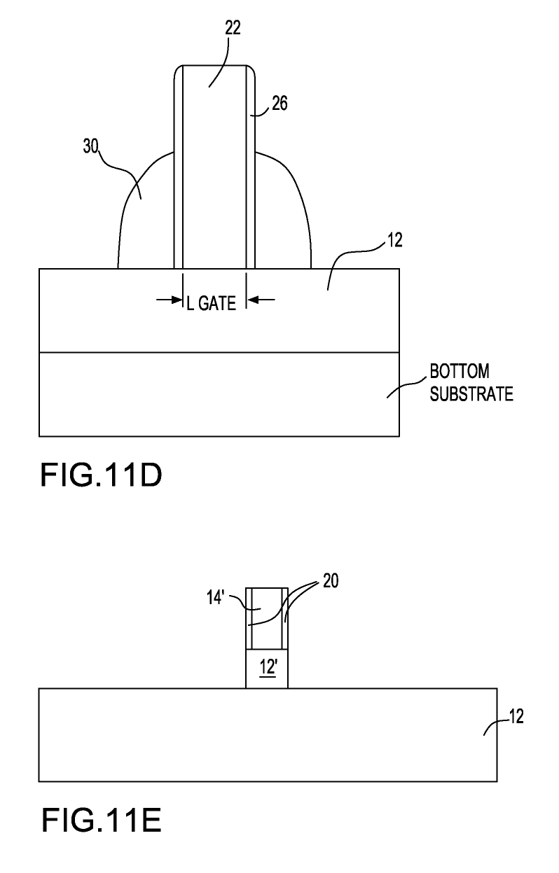

FIGS. 8A (top down view), 8B (cross sectional view through line A-A) and 8C (cross sectional view through line B-B) show the structure after patterning of the gate conductor 22 utilizing an etching process that selectively removes the exposed portions of the gate conductor 22 relative to the patterned photoresist 24 and after removing the patterned photoresist 24. As shown in FIG. 8A, the etching steps stops on the upper surface of the remaining hard mask 16′ as well as on the upper surface of the buried insulating layer 12.

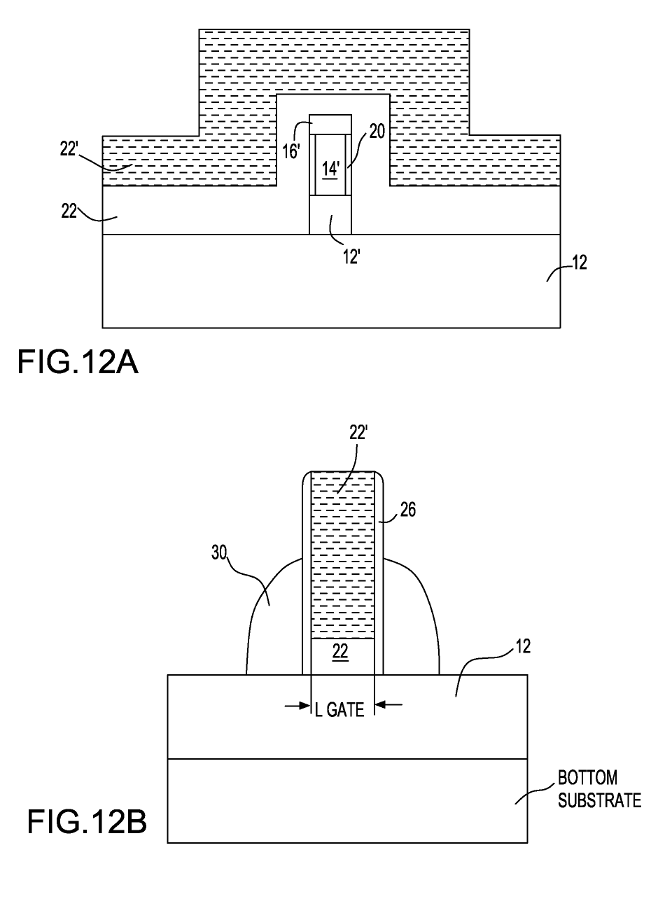

FIG. 9 illustrates the structure that is formed after performing another thermal process such as a thermal oxide process, which forms a thermal material (e.g., a thermal oxide) 26 on the gate sidewalls. Thermal material 26 typically has a thickness from about 3 to about 20 nm. The thermal material 26 serves to protect the gate sidewalls and/or to act as a spacer for a subsequent source/drain extension ion implantation step.

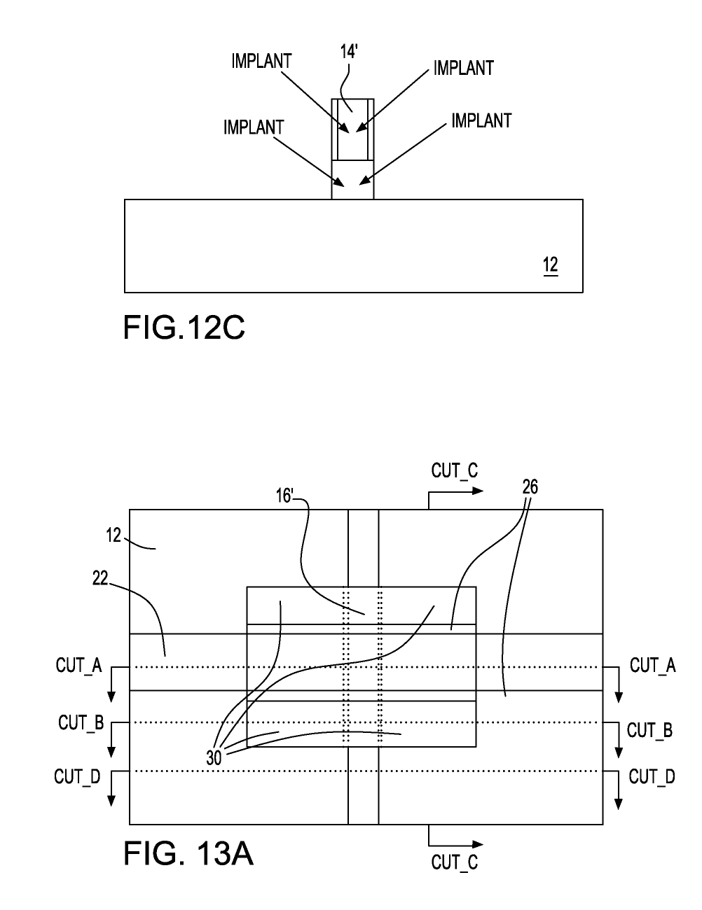

FIG. 10 illustrates the structure during the formation of an angled ion implantation which forms either source/drain extension regions and/or halo implants into the semiconductor Fin 14. In this drawing, reference numeral 28 denotes this angled ion implantation process. All the ion implantations used in this step of the present invention are the same as those used for conventional FinFET fabrication.

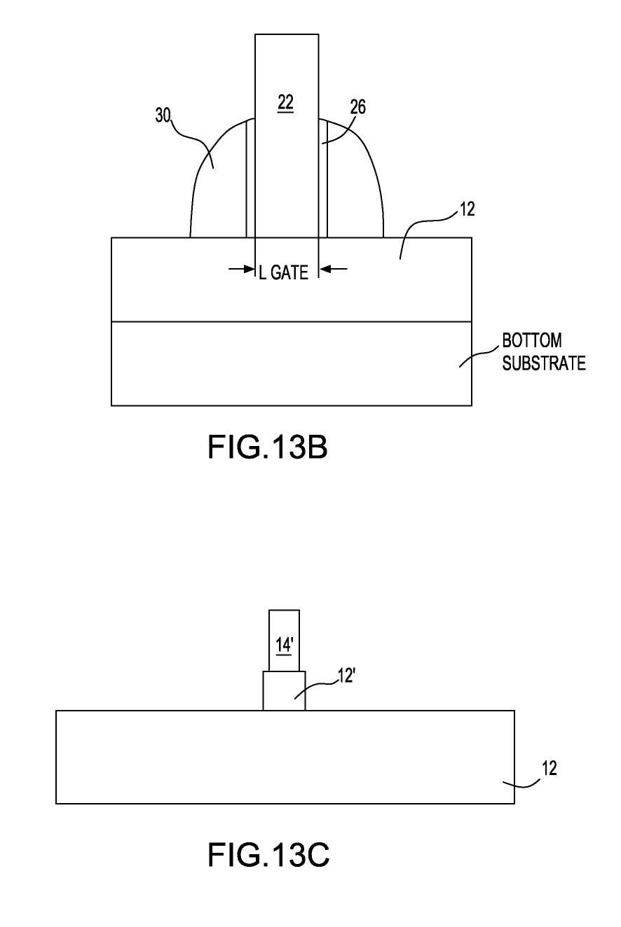

FIGS. 11A (top down view), 11B (cross sectional view through line A-A), 11C (cross sectional view through line B-B), 11D (cross sectional view through line C-C) and 11E (cross sectional view through line D-D) show the structure after forming a dielectric spacer 30. The dielectric spacer 30 is typically comprised of an oxide, nitride and/or oxynitride, with nitride spacers being highly preferred. The dielectric spacer 30 is formed by deposition of a blanket layer of dielectric followed by etching. The dielectric spacer 30 is located on the gate sidewalls which is clearly shown in FIG. 11C. It is noted that in FIG. 11E Lgate denotes the length of the gate.

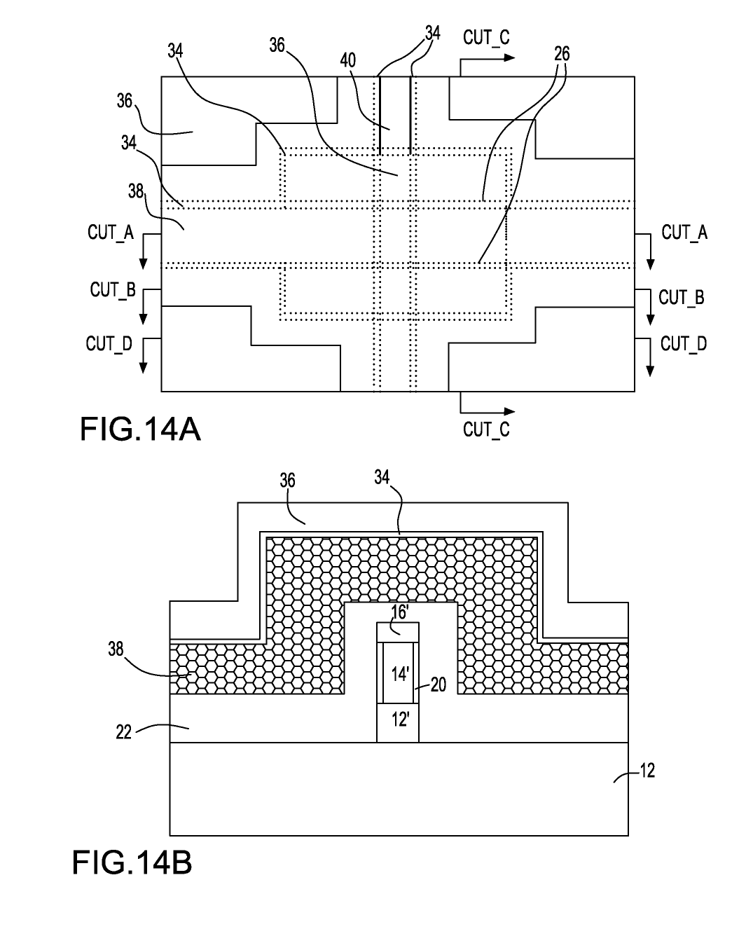

FIGS. 12A (cross sectional view through line A-A of FIG. 11A), 12B (cross sectional view through line C-C) and 12C (cross sectional view through line D-D) show the structure that is formed after source/drain ion implantation and after performing an amorphization ion implant into an upper portion of the gate conductor 22. In the drawings, reference numeral 22′ denotes the upper portion of the gate conductor 22 that receives the amorphization ion implantation.

The source/drain ion implantation includes the ion implantation of a p-type dopant or an n-type dopant into portions of the semiconductor Fin 14′. The source/drain ion implantation also dopes the gate conductor 22. Conventional source/drain ion implantations that are well known those skilled in the art can be used.

The amorphization ion implantation (which typically, but not necessarily always follows the source/drain ion implantation) includes ion implantation of an amorphizing ion such as Ge and/or Xe into portions of the gate conductor 22. Preferably, Ge is used as the amorphizing ion. The amorphization ion implantation is performed utilizing conditions which convert from about 20 to about 40 nm of the gate conductor 22, as measured from an exposed outer surface inward, into an amorphized region 22′. The amorphized region 22′ is used in the present invention to create and/or memorize the stress which be subsequently introduced to the structure.

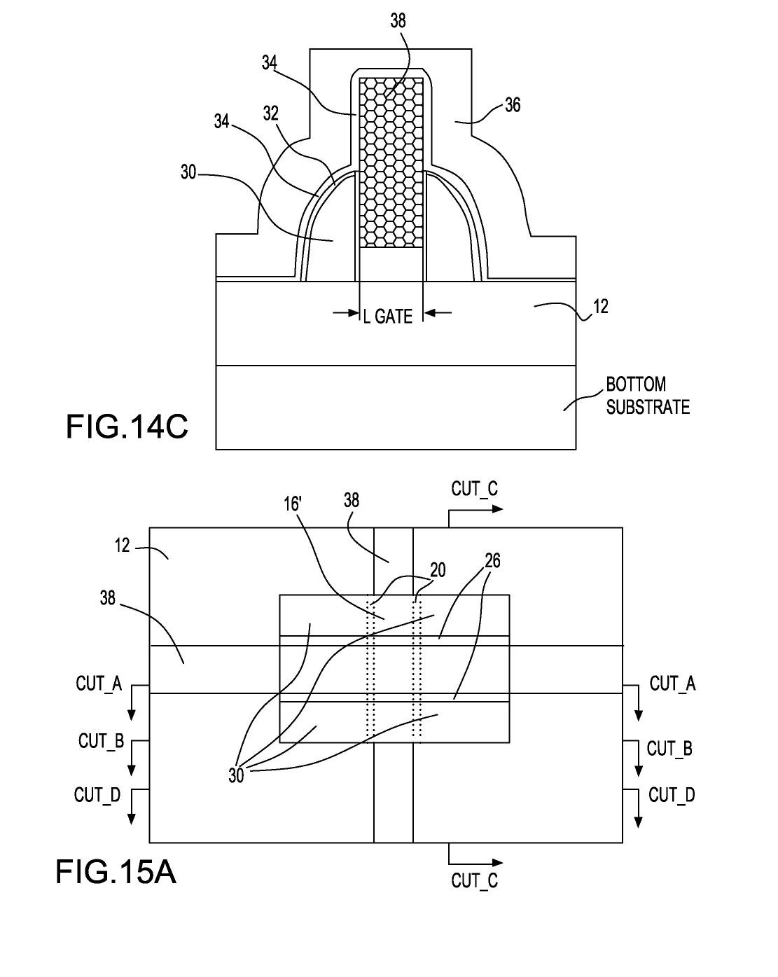

FIGS. 13A (top down view), 13B (cross sectional view through line C-C) and 13C (cross sectional through line D-D) show the structure that is formed after performing a source/drain activation anneal to active dopants previously introduced into the structure and after performing an isotropic etch remove the thermal material 26 from the sidewalls of the gate conductor 22. The source/drain activation anneal is performed utilizing conventional techniques well known to those skilled in the art. Typically, activation occurs when annealing at a temperature of about 800° C. or greater. The isotropic etch is performed utilizing an etchant that selectively removes the thermal material 26 from the sidewalls of the gate conductor 22 which are not protected by the dielectric spacer 30.

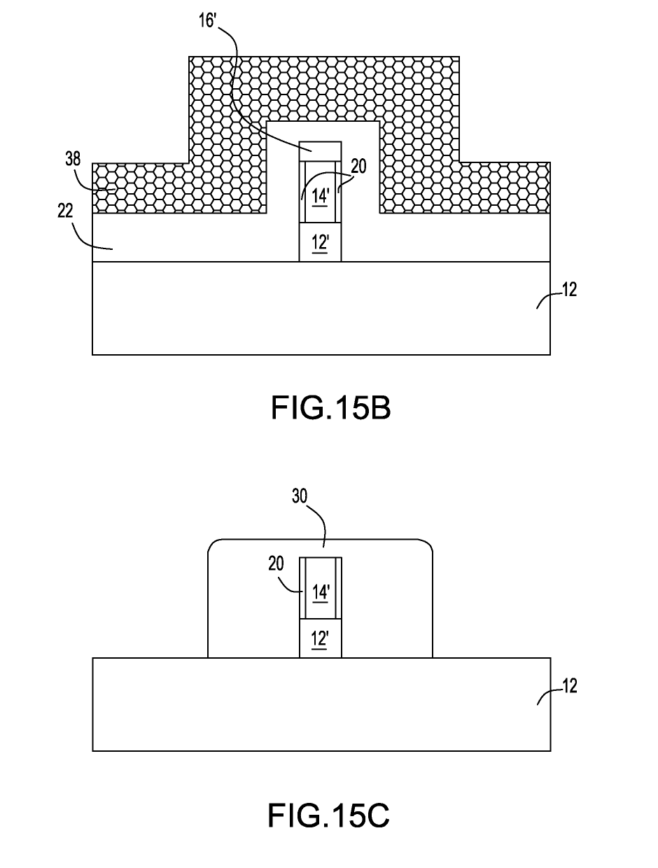

FIGS. 14A (top down view), 14B (cross sectional view through line A-A) and 14C (cross sectional view through line C-C) show the structure that is formed after forming a material stack comprising, from bottom to top, a silicide metal 32, an etch stop layer 34, and a stressed film 36 on the structure and after performing a silicidation process. During the silicidation anneal, the stress produced by the stressed film 36 can be memorized by the metal silicide formed by reacting the silicide metal with the amorphized portion of the gate conductor 22′. In the drawings, reference numeral 38 denotes the metal silicide that is formed.

The term “silicide metal” is used in the present application to denote any metal that is capable of reacting with a Si-containing material to form a silicide. Illustrative examples of such silicide metals that can be used in the present invention, include, Ti, Ni, W, Pt, Co and Pd. Preferably, Ni is used in the present invention as the silicide metal. The silicide metal is formed utilizing any conventional deposition process including CVD, PECVD, plating, sputtering and chemical solution deposition. The thickness of the layer of silicide metal that is formed is typically from about 5 to about 50 nm, with a thickness from about 10 to about 20 nm being even more typical.

The etch stopper layer 34 comprises any material that can provide protection of the device from a latter stressed film etching processing step. The etch stopper layer, e.g., a layer of TiN, 34 is formed utilizing any conventional deposition process and its thickness is typically from about 5 to about 10 nm.

The stressed film 36 may be compressively stressed (preferred when pFinFETs are being formed) or tensilely stressed (preferred when nFinFETs are being formed). The stressed film 36 may comprise an insulating material such as silicon nitride, a conductive material or a semiconductive material. Preferably, silicon nitride is used as the stressed film.

When a compressively stressed film 36 is employed, a PECVD process as disclosed in U.S. Patent Application Publication No. 2003/0040158 or in A. Tarraf et al. “Stress Investigation of PECVD Dielectric Layers for Advanced Optical MEMs,” J. Micromech. Microeng. Vol. 14, pp. 317-323 (2004) or any other suitable deposition technique such as high-density plasma (HPD) deposition can be used.

When a tensilely stressed film 36 is used, a low pressure chemical vapor deposition (LPCVD) process or a PECVD such as described in that above mentioned references or any other suitable deposition technique well known in the art can be used.

In some embodiments, block masks can be used to form both types of stressed films in the structure. This particular embodiment is not however illustrated in the drawings.

After forming the stressed film, a silicidation process is performed. The silicidation process includes annealing at a temperature that is capable of forming a silicide by reacting the silicide metal with the underlying Si-containing gate conductor. The annealing is typically performed in a gas atmosphere, e.g., He, Ar, N₂ or forming gas, at relatively low temperatures ranging from about 100° C. to about 600° C., preferably from about 300° C. to about 500° C., by using a continuous heating regime or various ramp and soak heating cycles.

This annealing step preserves the stress in the stressed film 36 and results in a metal silicide 38 on the gate conductor 22 that “memorizes” the corresponding stress state of the adjacent stressed film 26. For example, under tensile stress applied by an overlying tensilely stressed film 36, the metal silicide 38 formed on the gate conductor 22 obtains the intrinsic tensile stress during this annealing stress. Similarly, under compressive stress applied by an overlying compressively stressed film 36, the metal silicide 38 formed on the gate conductor 22 obtains the intrinsic compressive stress during this annealing stress.

The stress memorization technique as described hereinabove allows subsequent removal of the stressed films 36 and the etch stop layer 34 from the FinFET devices such as is shown in the remaining drawings of the present invention.

It should be noted that during this silicide anneal, silicide regions 40 are typically formed atop the source and drain regions of the FinFET device as well.

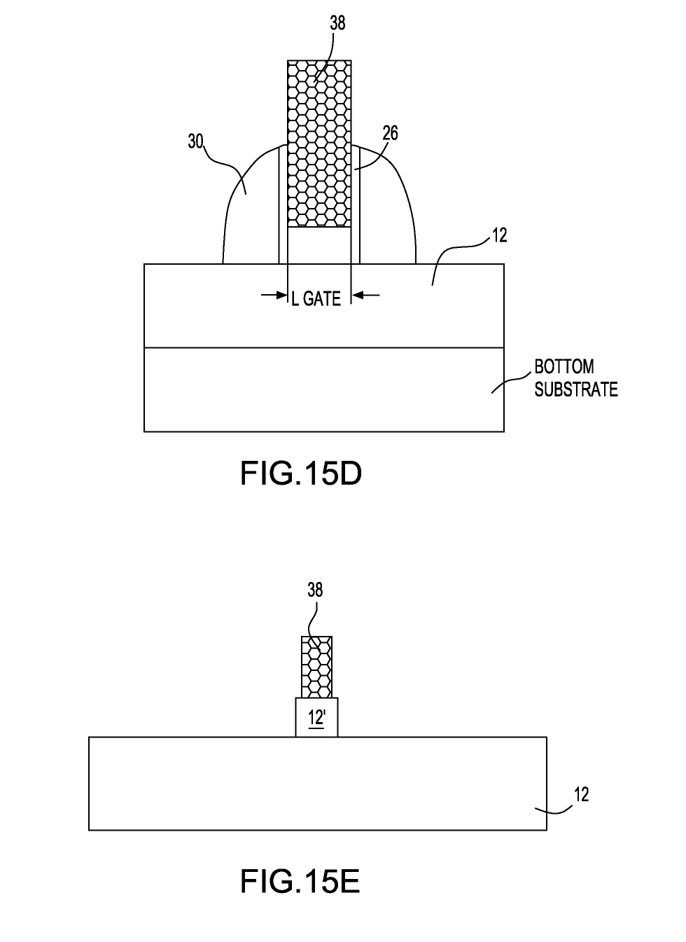

Specifically, FIGS. 15 A (top down view), 15B (cross sectional view through line A-A), 15C (cross sectional view through line B-B), 15D (cross sectional view through line C-C) and 15E (cross sectional view through line D-D) shows the structure after removing the stressed film 36 and the etch stop layer 34 as well as removing any residual silicide metal 32 from atop dielectric spacer 30 and the buried insulating layer 12. Typically, various etching steps are used in performing the removal of the above-mentioned materials from the structure.

After forming the structure shown in FIGS. 15A-15E conventional processing steps to finish the fabrication of the FinFET device including metal contact formation can be performed.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising:
at least one FinFET device located on a surface of a substrate, said at least one FinFET device including a semiconductor Fin located directly on said substrate, a gate dielectric located on at least sidewalls of said semiconductor Fin and a gate conductor located on the surface of the substrate and at least laterally adjacent to the gate dielectric located on the sidewalls of the semiconductor Fin; and
a stressed silicide located directly on the gate conductor which introduces stress into a channel region of the FinFET device.

2. The semiconductor structure of claim 1 wherein said semiconductor Fin comprises a Si-containing semiconductor material.

3. The semiconductor structure of claim 1 wherein said substrate is a semiconductor-on-insulator including a buried insulating layer, and said at least one FinFET device, said semiconductor Fin and said gate conductor are located on a surface of said buried insulating layer.

4. The semiconductor structure of claim 3 wherein said buried insulating layer includes a raised portion in which said semiconductor Fin is located on.

5. The semiconductor structure of claim 1 wherein said stressed silicide is under compressive stress.

6. The semiconductor structure of claim 1 wherein said stressed silicide is under tensile stress.

7. The semiconductor structure of claim 1 wherein said gate conductor comprises polysilicon.

8. The semiconductor structure of claim 1 wherein said gate dielectric comprises a thermal oxide.

9. The semiconductor structure of claim 1 wherein said stressed silicide is NiSi.

10. The semiconductor structure of claim 1 wherein said semiconductor Fin includes a hard mask material located on an upper surface thereof, said hard mask material separates said upper surface of said semiconductor Fin from said gate conductor.

11. A method of fabricating a semiconductor structure comprising:
forming a structure including at least one FinFET device located on a surface of a substrate, said at least one FinFET device including a semiconductor Fin located directly on said substrate, a gate dielectric located on at least sidewalls of said semiconductor Fin and a gate conductor including an upper amorphized region located on the surface of the substrate and at least laterally adjacent to the gate dielectric located on the sidewalls of the semiconductor Fin;
forming a material stack comprising, from bottom to top, a silicide metal, an etch stop layer and a stressed film on said structure; and
performing a silicide anneal that causes reaction between said silicide metal and said amorphized upper portion of said gate conductor converting the upper amorphized portion of said gate conductor into a metal silicide, said metal silicide having the same stress type as that of said stressed film.

12. The method of claim 11 wherein. wherein said substrate is a semiconductor-on-insulator including a buried insulating layer, and said at least one FinFET device, said semiconductor Fin and said gate conductor are located on a surface of said buried insulating layer.

13. The method of claim 12 wherein said semiconductor Fin is located on a raised portion of said buried insulating layer.

14. The method of claim 11 wherein said upper amorphized region is formed by implanting an amorphizing ion into said gate conductor.

15. The method of claim 11 wherein said stressed film is under tensile stress and is formed by low-pressure chemical vapor deposition or plasma enhanced chemical vapor deposition.

16. The method of claim 11 wherein said stressed film is under compressive stress and is formed by plasma enhanced chemical vapor deposition or high-density plasma deposition.

17. The method of claim 11 wherein said silicide anneal is performed in a gas atmosphere at a temperature from about 100° C. to about 600° C.

18. The method of claim 11 further comprising removing said material stack from said structure after said silicide anneal.

19. The method of claim 11 wherein said silicide metal comprises Ni and said silicide anneal forms a NiSi.

20. The method of claim 11 wherein said gate dielectric is formed by thermal oxidation.
